(19) United States
(12) Patent Application Publication
(10) Pub. No.: US 2025/0194110 A1
(43) Pub. Date: Jun. 12, 2025

(54) SEMICONDUCTOR DEVICE

(71) Applicant: Samsung Electronics Co., Ltd., Suwon-si (KR)

(72) Inventors: Jihye Lee, Suwon-si (KR); Jumi Bak, Suwon-si (KR); Soyoung Shin, Suwon-si (KR); Songyun Kang, Suwon-si (KR); Youngrok Kwon, Suwon-si (KR); Sunggil Kim, Suwon-si (KR); Seongkeun Cho, Suwon-si (KR)

(21) Appl. No.: 18/777,352

(22) Filed: Jul. 18, 2024

(30) Foreign Application Priority Data
Dec. 8, 2023 (KR) 10-2023-0178054

(51) Int. Cl. H10B 80/00; H01L 23/00; H01L 25/00; H01L 25/065; H01L 25/18; H10B 41/27; H10B 43/27

(52) U.S. Cl. CPC H10B 80/00; H01L 24/08; H01L 24/80; H01L 25/0657; H01L 25/18; H01L 25/50; H10B 41/27; H10B 43/27; H01L 2224/08145; H01L 2224/80895; H01L 2224/80896; H01L 2924/1431; H01L 2924/14511

(57) ABSTRACT

A semiconductor device includes a cell structure including a cell region, a connection region, and a peripheral circuit connection region, wherein the peripheral circuit connection region includes an inner region and an outer region surrounding the inner region, and the cell structure includes a plug passing through a stack insulating layer in the inner region, a conductive base layer spaced apart from the plug in a horizontal direction in the outer region, a cover insulating layer located on an upper surface of the conductive base layer; and a common source layer having a portion on an upper surface of the cover insulating layer.

### CROSS-REFERENCE TO RELATED APPLICATION

This application is based on and claims priority under 35 U.S.C. § 119 to Korean Patent Application No. 10-2023-0178054, filed on Dec. 8, 2023, in the Korean Intellectual Property Office, the disclosure of which is incorporated by reference herein in its entirety.

### BACKGROUND

The inventive concept relates to a semiconductor device, and more particularly, to a semiconductor device including a conductive base layer located in an outer region included in a peripheral circuit connection region.

There has been demand for a semiconductor device for storing high-capacity data in an electronic system that requires data storage. As data storage capacity increases, there is demand to increase the integration of semiconductor devices to satisfy the excellent performance and low prices demanded by consumers. In the case of two-dimensional (2D) or planar semiconductor devices, the integration is mainly determined by an area occupied by a unit memory cell and is therefore greatly affected by a level of micropattern formation technology. However, ultra-expensive equipment is required to refine patterns, and thus the integration of 2D semiconductor devices increases but is still limited. Accordingly, three-dimensional (3D) semiconductor memory devices having memory cells arranged three-dimensionally have been proposed.

### SUMMARY

The inventive concept may provide a semiconductor device with improved electrical characteristics and reliability.

The objects to be achieved by the inventive concept are not limited to the technical objects described above and other objects that are not stated herein will be clearly understood by those skilled in the art from the following specifications.

According to an aspect of the inventive concept, a semiconductor device includes a peripheral circuit structure, and a cell structure stacked on the peripheral circuit structure and including a cell region, a connection region, and a peripheral circuit connection region, wherein the peripheral circuit connection region includes an inner region and an outer region surrounding the inner region, and the cell structure includes gate electrodes apart from each other in a vertical direction in the cell region, a channel structure passing through each of the gate electrodes to extend in the vertical direction in the cell region, the channel structure including a first end adjacent to the peripheral circuit structure and a second end opposite to the first end, a stack insulating layer in the connection region and the peripheral circuit connection region, the stack insulating layer surrounding the gate electrodes, a plug passing through the stack insulating layer in the inner region, a conductive base layer on an upper surface of the stack insulating layer in the outer region and apart from the plug in a horizontal direction, a cover insulating layer on an upper surface of the conductive base layer; and a common source layer connected to the second end of the channel structure in the cell region and having a portion on an upper surface of the cover insulating layer.

According to another aspect of the inventive concept, a semiconductor device includes a peripheral circuit structure; and a cell structure stacked on the peripheral circuit structure and including a cell region, a connection region, and a peripheral circuit connection region, wherein the peripheral circuit connection region includes an inner region and an outer region surrounding the inner region, the cell structure includes: gate electrodes apart from each other in a vertical direction in the cell region; a channel structure passing through each of the gate electrodes to extend in the vertical direction in the cell region, the channel structure including a first end adjacent to the peripheral circuit structure and a second end opposite to the first end; a stack insulating layer in the connection region and the peripheral circuit connection region, the stack insulating layer surrounding the gate electrodes and having a first thickness; a conductive base layer on an upper surface of the stack insulating layer in the outer region; a cover insulating layer on an upper surface of the conductive base layer, the cover insulating layer having a second thickness; and a common source layer connected to the second end of the channel structure in the cell region and having a portion on an upper surface of the cover insulating layer, and the second thickness is greater than the first thickness.

According to another aspect of the inventive concept, a semiconductor device includes a peripheral circuit structure including a peripheral circuit transistor, a peripheral circuit wiring structure, and a first connection pad; and a cell structure stacked on the peripheral circuit structure and including a cell region, a connection region, and a peripheral circuit connection region, wherein the peripheral circuit connection region includes an inner region and an outer region surrounding the inner region, wherein the cell structure further includes: a second connection pad bonded to the first connection pad of the peripheral circuit structure; gate electrodes and mold insulating layers alternately stacked one by one in a vertical direction on the second connection pad in the cell region; a channel structure passing through the gate electrodes and mold insulating layers to extend in the vertical direction in the cell region, the channel structure including a first end adjacent to the peripheral circuit structure and a second end opposite to the first end, the channel structure protruding above an uppermost gate electrode from among the gate electrodes; a common source layer in the cell region and being in contact with a channel layer of the channel structure protruding on the uppermost gate electrode; a pad portion extending from the gate electrodes and having a stepwise shape in the connection region; a first plug connected to the pad portion and passing through the pad portion to extend in the vertical direction; a stack insulating layer surrounding the gate electrodes in the connection region and the peripheral circuit connection region; a second plug passing through the stack insulating layer in the inner region; a conductive base layer on an upper surface of the stack insulating layer in the outer region and apart from the second plug; and a cover insulating layer on an upper surface of the conductive base layer.

### BRIEF DESCRIPTION OF THE DRAWINGS

Embodiments will be more clearly understood from the following detailed description taken in conjunction with the accompanying drawings in which:

FIG. 1 is a block diagram of a semiconductor device according to embodiments;

FIG. 2 is a circuit diagram showing a memory block according to embodiments;

FIG. 3 is a perspective view showing a representative configuration of a semiconductor device according to embodiments;

FIG. 4 is a plan layout diagram of the semiconductor device of FIG. 3;

FIG. 5 is an enlarged layout diagram of a portion A of FIG. 4;

FIG. 6 is a cross-sectional view taken along lines B1-B1′ and B2-B2′ of FIG. 5;

FIG. 7 is a cross-sectional view taken along lines B1-B1′ and B2-B2′ of FIG. 5;

FIG. 8 is a cross-sectional view taken along lines B1-B1′ and B2-B2′ of FIG. 5;

FIGS. 9A to 9G are schematic diagrams showing a method of manufacturing a semiconductor device according to embodiments and are cross-sectional views taken along lines B1-B1′ and B2-B2′ of FIG. 5;

FIG. 10 is a schematic diagram showing a data storage system including a semiconductor device according to embodiments;

FIG. 11 is a schematic perspective diagram showing a data storage system including a semiconductor device according to embodiments; and

FIG. 12 is a schematic diagram showing semiconductor packages according to embodiments and is a cross-sectional view taken along a line II-II′ of FIG. 11.

### DETAILED DESCRIPTION OF THE EMBODIMENTS

Hereinafter, embodiments of the technical spirit of the inventive concept will be described in detail with reference to the attached drawings.

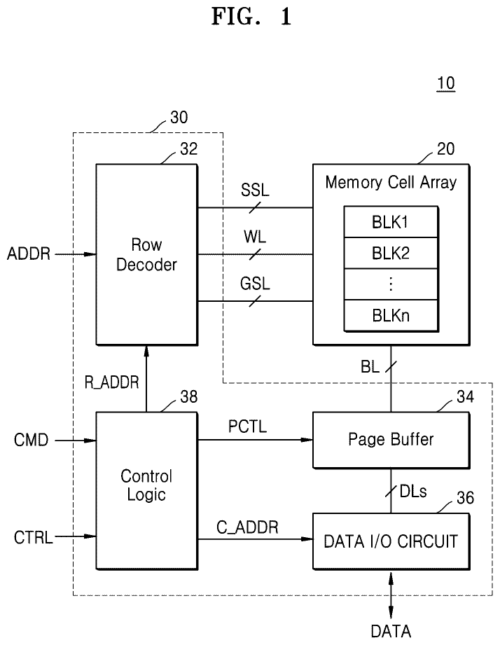

FIG. 1 is a block diagram of a semiconductor device 10 according to embodiments.

Referring to FIG. 1, the semiconductor device 10 may include a memory cell array 20 and a peripheral circuit 30. The memory cell array 20 includes a plurality of memory cell blocks BLK1, BLK2, through BLKn. Each of the plurality of memory cell blocks BLK1, BLK2, through BLKn may include a plurality of memory cells. The memory cell blocks BLK1, BLK2, through BLKn may be connected to the peripheral circuit 30 through a bit line BL, a word line WL, a string selection line SSL, and a ground selection line GSL.

The peripheral circuit 30 may include a row decoder 32, a page buffer 34, a data input/output circuit 36, and control logic 38. Although not shown in FIG. 1, the peripheral circuit 30 may further include an input/output interface, a column logic, a voltage generator, a pre-decoder, a temperature sensor, a command decoder, an address decoder, and an amplifier circuit.

The memory cell array 20 may be connected to the page buffer 34 through the bit line BL, and may be connected to the row decoder 32 through the word line WL, the string selection line SSL, and the ground selection line GSL. In the memory cell array 20, each of the plurality of memory cells included in the plurality of memory cell blocks BLK1, BLK2, through BLKn may be a flash memory cell. The memory cell array 20 may include a three-dimensional (3D) memory cell array. The 3D memory cell array may include a plurality of NAND strings, and each NAND string may include a plurality of memory cells connected to a plurality of word lines WL that are vertically stacked on a substrate.

The peripheral circuit 30 may receive an address ADDR, a command CMD, and a control signal CTRL from the outside of the semiconductor device 10 and transmit and receive data DATA to and from devices outside the semiconductor device 10.

The row decoder 32 may select at least one of the plurality of memory cell blocks BLK1, BLK2, through BLKn in response to the address ADDR from the outside and select the word line WL, the string selection line SSL, and the ground selection line GSL of the selected memory cell block. The row decoder 32 may transmit a voltage for performing a memory operation to the word line WL of the selected memory cell block.

The page buffer 34 may be connected to the memory cell array 20 through the bit line BL. The page buffer 34 may operate as a write driver during a program operation to apply, to the bit line BL, a voltage according to the data DATA to be stored in the memory cell array 20 and operate as a sense amplifier during a read operation to detect data stored in the memory cell array 20. The page buffer 34 may operate according to a control signal PCTL provided from the control logic 38.

The data input/output circuit 36 may be connected to the page buffer 34 through data lines DLs. The data input/output circuit 36 may receive the data DATA from a memory controller (not shown) during the program operation and provide program data DATA to the page buffer 34 based on a column address C_ADDR provided from the control logic 38. The data input/output circuit 36 may provide read data DATA stored in the page buffer 34 to the memory controller based on the column address C_ADDR provided from the control logic 38 during the read operation.

The data input/output circuit 36 may transmit an input address or command to the control logic 38 or the row decoder 32. The peripheral circuit 30 may further include an electro static discharge (ESD) circuit and a pull-up/pull-down driver.

The control logic 38 may receive the command CMD and the control signal CTRL from the memory controller. The control logic 38 may provide a row address R_ADDR to the row decoder 32 and provide the column address C_ADDR to the data input/output circuit 36. The control logic 38 may generate various internal control signals used within the semiconductor device 10 in response to the control signal CTRL. For example, the control logic 38 may adjust a voltage level provided to the word line WL and the bit line BL when performing a memory operation such as a program operation or an erase operation.

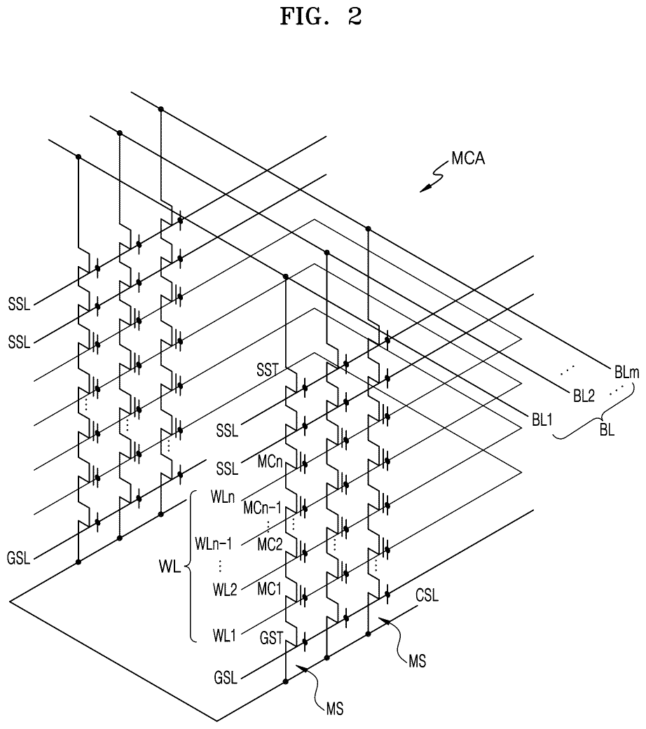

FIG. 2 is a circuit diagram showing a memory block according to embodiments.

Referring to FIG. 2, a memory cell array MCA may include a plurality of memory cell strings MS. The memory cell array MCA may include a plurality of bit lines BL: BL1, BL2, through BLm, a plurality of word lines WL: WL1, WL2, through WLn−1, and WLn, at least one string selection line SSL, at least one ground selection line GSL, and a common source line CSL. The plurality of memory cell strings MS may be formed between the plurality of bit lines BL: BL1, BL2, through BLm and the common source line CSL. Although FIG. 2 illustrates a case in which each of the plurality of memory cell strings MS includes two string selection lines SSL, the technical spirit of the inventive concept is not limited thereto. For example, each of the plurality of memory cell strings MS may include one string selection line SSL.

Each of the plurality of memory cell strings MS may include a string selection transistor SST, a ground selection transistor GST, and a plurality of memory cell transistors MC1, MC2, through MCn−1, and MCn. A drain region of the string selection transistor SST may be connected to the bit lines BL: BL1, BL2, through BLm and a source region of the ground selection transistor GST may be connected to the common source line CSL. The common source line CSL may be a region to which the source regions of a plurality of ground selection transistors GST are commonly connected.

The string selection transistor SST may be connected to the string selection line SSL, and the ground selection transistor GST may be connected to the ground selection line GSL. The plurality of memory cell transistors MC1, MC2, through MCn−1, and MCn may be connected to the plurality of word lines WL: WL1, WL2, through WLn−1, and WLn, respectively.

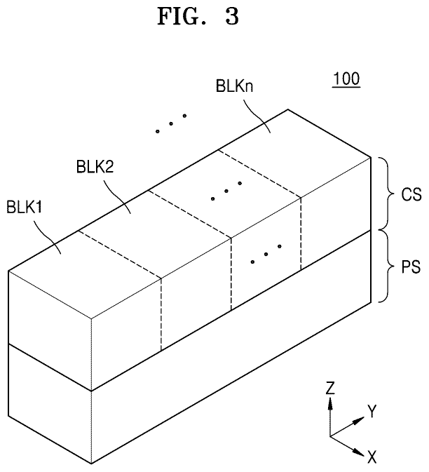

FIG. 3 is a perspective view showing a representative configuration of a semiconductor device according to embodiments.

Referring to FIG. 3, a semiconductor device 100 may include a peripheral circuit structure PS and a cell structure CS on the peripheral circuit structure PS.

The peripheral circuit structure PS may include the peripheral circuit 30 described with reference to FIG. 1. The cell structure CS may include the memory cell array 20 described with reference to FIG. 1.

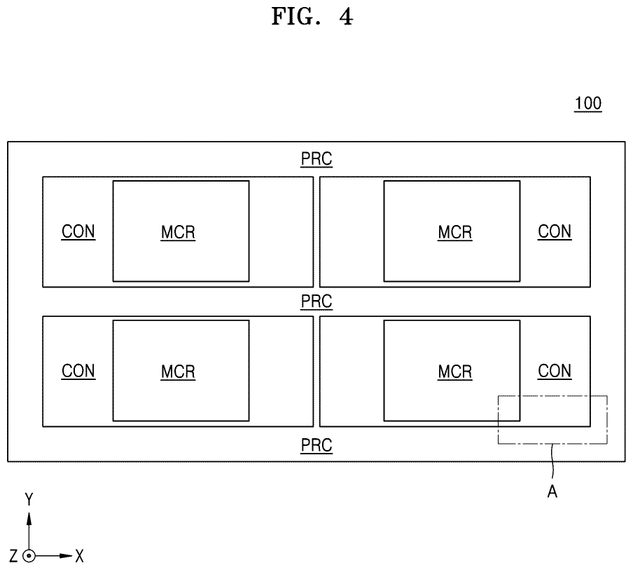

The cell structure CS may include the plurality of memory cell blocks BLK1, BLK2, through BLKn. Each of the plurality of memory cell blocks BLK1, BLK2, through BLKn may include memory cells arranged three-dimensionally. For example, the plurality of memory cell blocks BLK1, BLK2, through BLKn may be sequentially arranged in a second horizontal direction Y. Definitions of a first horizontal direction X, the second horizontal direction Y, and a vertical direction Z in FIG. 3 are the same as definition of the first horizontal direction X, the second horizontal direction Y, and the vertical direction Z in FIGS. 4 to 6, respectively.

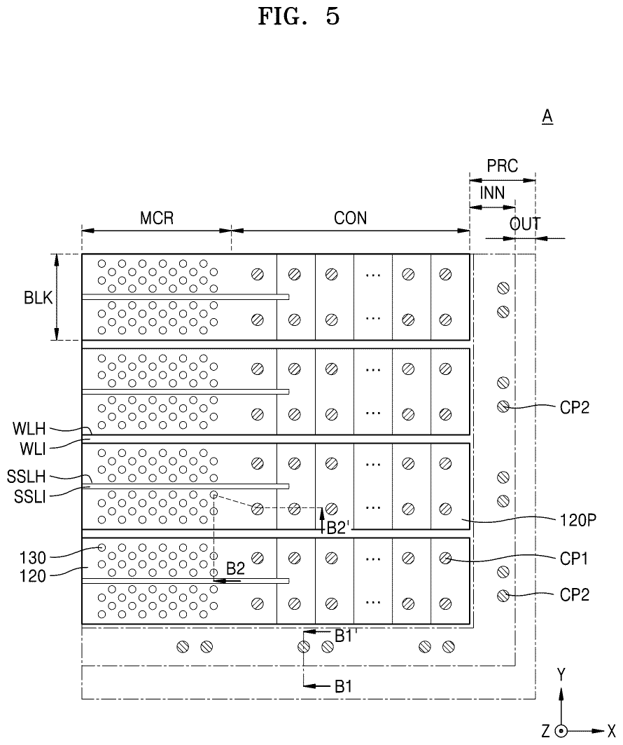

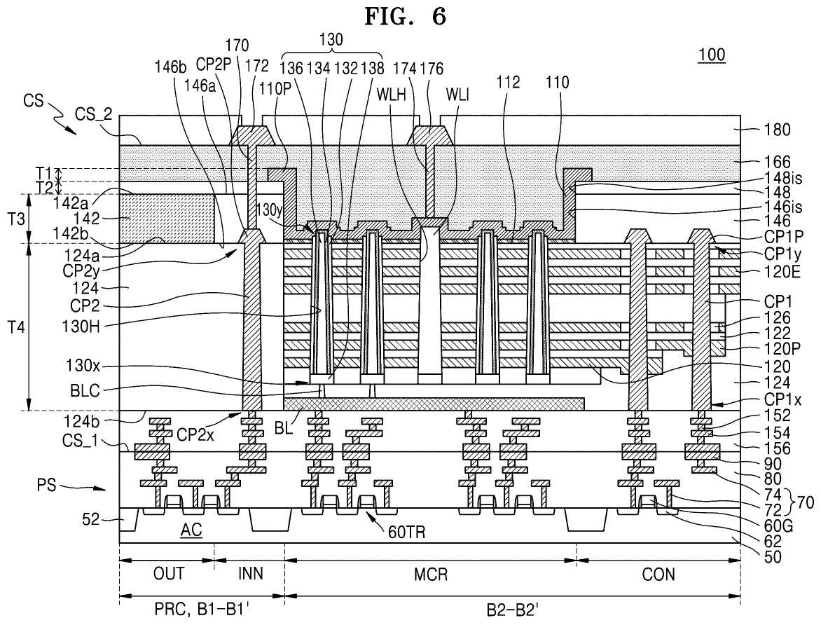

FIG. 4 is a plan layout diagram of the semiconductor device of FIG. 3. FIG. 5 is an enlarged layout diagram of a portion A of FIG. 4. FIG. 6 is a cross-sectional view taken along lines B1-B1′ and B2-B2′ of FIG. 5.

Referring to FIGS. 4 to 6, the semiconductor device 100 includes the cell structure CS and the peripheral circuit structure PS that overlap each other in the vertical direction Z. The cell structure CS may include the memory cell array 20 described with reference to FIG. 1, and the peripheral circuit structure PS may include the peripheral circuit 30 described with reference to FIG. 1. The cell structure CS may correspond to a cell structure CS in FIG. 3, and the peripheral circuit structure PS may correspond to the peripheral circuit structure PS in FIG. 3.

In this specification, the first horizontal direction X is defined as a direction parallel to an upper surface of a substrate 50, and the second horizontal direction Y is defined as a direction parallel to the upper surface of the substrate 50 and intersecting with the first horizontal direction X, and the vertical direction Z is defined as a direction perpendicular to the upper surface of the substrate 50.

The peripheral circuit structure PS may include a peripheral circuit transistor 60TR and a peripheral circuit wiring structure 70 that are disposed on the substrate 50. An active region AC may be defined on the substrate 50 by a device separation layer 52, and the plurality of peripheral circuit transistors 60TR may be formed in the active region AC. The plurality of peripheral circuit transistors 60TR may include a peripheral circuit gate 60G and source/drain regions 62 located on each side of the peripheral circuit gate 60G.

The substrate 50 may be formed of or include a semiconductor material, such as a Group IV semiconductor, Groups III to V compound semiconductors, or Groups II to VI oxide semiconductors. For example, a Group IV semiconductor may include silicon (Si), germanium (Ge), or silicon-germanium (SiGe). The substrate 50 may be provided as a bulk wafer or an epitaxial layer. In another embodiment, the substrate 50 may include a silicon-on-insulator (SOI) substrate, or a germanium-on-insulator (GeOI) substrate.

The peripheral circuit wiring structure 70 may include a plurality of peripheral circuit contacts 72 and a plurality of peripheral circuit wiring layers 74. A first interlayer insulating layer 80 may be disposed on the substrate 50 to cover the peripheral circuit transistor 60TR and the peripheral circuit wiring structure 70. The plurality of peripheral circuit wiring layers 74 may have a multi-layer structure including a plurality of metal layers at different vertical levels. A connection pad 90 may be disposed above the first interlayer insulating layer 80. The first interlayer insulating layer 80 may not cover an upper surface of the connection pad 90. The peripheral circuit structure PS and the cell structure CS may be electrically connected to and bonded to each other by the connection pad 90.

The cell structure CS may include a cell region MCR, a connection region CON, and a peripheral circuit connection region PRC. As shown in FIG. 4, the connection region CON may be next to the cell region MCR in the first horizontal direction X, and the peripheral circuit connection region PRC may surround the cell region MCR and the connection region CON.

The peripheral circuit connection region PRC may include an inner region INN and an outer region OUT surrounding the inner region INN. The inner region INN may be a region in which a second plug CP2 is located. The outer region OUT may be a region that surrounds the inner region INN and in which the second plug CP2 is not located.

The cell region MCR may be a region in which the memory cell block BLK (refer to FIG. 5) including the plurality of memory cell strings MS (in FIG. 2) extending in the vertical direction Z is located. In the cell region MCR, a common source layer 110, gate electrodes 120, and a channel structure 130 passing through the gate electrodes 120 to extend in the vertical direction Z and connected to the common source layer 110 may be located. For example, each channel structure 130 may be completely or partially surrounded by each gate electrode 120 that it passes through as shown, e.g., in FIG. 5.

In the connection region CON, an extension 120E and a pad portion 120P that are connected to the plurality of gate electrodes 120 may be located. In the connection region CON, a first plug CP1 may be located to pass through the extension 120E and the pad portion 120P and to be electrically connected to the pad portion 120P. In the inner region INN of the peripheral circuit connection region PRC, the second plug CP2 extending in the vertical direction Z and electrically connected to the peripheral circuit wiring structure 70 may be located. The second plug CP2 may not be located in the outer region OUT of the peripheral circuit connection region PRC.

The cell structure CS may include a first surface CS_1 connected to the peripheral circuit structure PS and a second surface CS_2 opposite to the first surface CS_1. In FIG. 6, the first surface CS_1 of the cell structure CS is shown to be located at a lower side of the cell structure CS, and the second surface CS_2 of the cell structure CS is shown to be located at an upper side of the cell structure CS. Here, for convenience, as shown in FIG. 6, being located close to the first surface CS_1 of the cell structure CS is referred to as being located at a lower vertical level, and being located close to the second surface CS_2 of the cell structure CS is referred to as being located at a higher vertical level.

The gate electrodes 120 may be apart from each other in the vertical direction Z in the cell region MCR, and the gate electrodes 120 may be alternately stacked one by one with mold insulating layers 122.

The gate electrodes 120 may extend to the connection region CON. The portions of the gate electrodes 120 that are located in the connection region CON may be referred to as extensions 120E. The extensions 120E may have a horizontal length that gradually increases in a direction from the first surface CS_1 to the second surface CS_2 of the cell structure CS (i.e., in the vertical direction Z in FIG. 6). The extensions 120E may have a stepwise shape, and pad portions 120P may be connected to ends of the extensions 120E. The pad portion 120P may be a portion of the gate electrode 120. The pad portions 120P may have a greater thickness in the vertical direction Z than the extensions 120E. For example, the lowermost extension 120E may be the shortest in the first horizontal direction X, and each extension 120E may be longer in the first horizontal direction X than the extension 120E that is immediately beneath it.

Although not shown, the gate electrodes 120 may include a buried conductive layer and a conductive barrier layer surrounding an upper surface, a bottom surface, and a side surface of the buried conductive layer. For example, the buried conductive layer may include a metal such as tungsten, nickel, cobalt, or tantalum, metal silicide such as tungsten silicide, nickel silicide, cobalt silicide, or tantalum silicide, doped polysilicon, or a combination thereof. In some embodiments, the conductive barrier layer may include titanium nitride, tantalum nitride, tungsten nitride, or a combination thereof.

In embodiments, the gate electrodes 120 may correspond to the ground selection line GSL (in FIG. 2), the word line WL (in FIG. 2), and at least one string selection line SSL (in FIG. 2), which constitute the memory cell string MS (in FIG. 2). For example, the uppermost gate electrode 120 as shown in FIG. 6 may function as the ground selection line GSL (in FIG. 2), two lowermost gate electrodes 120 as shown in FIG. 6 may function as the string selection line SSL (in FIG. 2), and the other gate electrodes 120 may function as the word line WL (in FIG. 2). Accordingly, provided may be the memory cell MS (in FIG. 2) in which the ground selection transistor GST (in FIG. 2), the string selection transistor SST (in FIG. 2), and memory cell transistors MC1, MC2, through MCn−1, and MCn (in FIG. 2) therebetween are connected in series to each other. In some embodiments, at least one of the gate electrodes 120 may function as a dummy word line, but the inventive concept is not limited thereto.

A stack separation insulating layer WLI may be located in a stack separation opening WLH passing through the gate electrodes 120 to extend in the vertical direction Z and the mold insulating layers 122. The stack separation insulating layer WLI may have an upper surface at a vertical level higher than the uppermost gate electrode 120 and may protrude in the vertical direction Z above the uppermost gate electrode 120.

As shown in FIG. 5, the gate electrodes 120 located between a pair of adjacent stack separation openings WLH may constitute one block BLK. At least one gate electrode 120 (e.g., the uppermost gate electrode 120) within one block BLK may be separated into two gate electrodes 120 by a string separation opening SSLH. A string separation insulating layer SSLI may be located within the string separation opening SSLH.

A stack insulating layer 124 may be located to surround the gate electrodes 120, extensions 120E, and pad portions 120P in the connection region CON and the peripheral circuit connection region PRC. From a plan view, the stack insulating layer 124 may be located to surround the gate electrodes 120. In the peripheral circuit connection region PRC, an upper surface 124a of the stack insulating layer 124 may have the same level as an upper surface of the uppermost mold insulating layer 122 from among the mold insulating layers 122 in the cell region MCR.

The channel structure 130 may include a first end 130x in the vertical direction Z located close to the peripheral circuit structure PS and a second end 130y opposite to the first end 130x. In embodiments, the channel structure 130 may have an inclined sidewall such that a width of the first end 130x is greater than a width of the second end 130y. The first end 130x of the channel structure 130 may be electrically connected to the bit line BL through a bit line contact BLC, and the second end 130y of the channel structure 130 may be connected to the common source layer 110.

The channel structure 130 may be located in a channel hole 130H passing through the gate electrodes 120 and the mold insulating layers 122 to extend vertically and may include a gate insulating layer 132, a channel layer 134, a buried insulating layer 136, and a drain region 138. The channel layer 134 may have a cylindrical shape, the gate insulating layer 132 may be located on an outer wall of the channel layer 134, and the buried insulating layer 136 may be located on an inner wall of the channel layer 134. The channel layer 134 may be located on sidewalls of the buried insulating layer 136 and on an upper surface of the buried insulating layer 136. The gate insulating layer 132 may not be located on an upper surface of the channel layer 134, for example, on the upper surface of the channel layer 134 located at the second end 130y of the channel structure 130.

Although not shown, the gate insulating layer 132 may have a structure that sequentially includes a tunneling dielectric layer, a charge storage layer, and a blocking dielectric layer on the outer wall of the channel layer 134. The relative thicknesses of the tunneling dielectric layer, the charge storage layer, and the blocking dielectric layer that constitute the gate insulating layer 132 may vary.

The tunneling dielectric layer may be formed of or include silicon oxide, hafnium oxide, aluminum oxide, zirconium oxide, and tantalum oxide. The charge storage layer may be a region in which electrons passing through the tunneling dielectric layer from the channel layer 134 are to be stored, and may be formed of or include silicon nitride, boron nitride, silicon boron nitride, or polysilicon doped with impurities. The blocking dielectric layer may be formed of or include silicon oxide, silicon nitride, or a metal oxide with a higher dielectric constant than silicon oxide. The metal oxide may be hafnium oxide, aluminum oxide, zirconium oxide, tantalum oxide, or a combination thereof.

An etch stop layer 112 may be located on the uppermost gate electrode 120, and the etch stop layer 112 may be formed of or include polysilicon. In some embodiments, the etch stop layer 112 may be omitted.

The common source layer 110 may be connected to the second end 130y of the channel structure 130 on the etch stop layer 112. The common source layer 110 may be conformally formed to cover an upper surface of the stack separation insulating layer WLI. From a plan view, the common source layer 110 may be located in an entire region of the cell region MCR.

A portion of the common source layer 110, which is in contact with the etch stop layer 112, may have an upper surface at a different vertical level from a portion of the common source layer 110, which is in contact with the second end 130y of the channel structure 130. In some embodiments, a portion of the common source layer 110, which is in contact with the stack separation insulating layer WLI, may have an upper surface at a different vertical level from a portion of the common source layer 110, which is in contact with the second end 130y of the channel structure 130.

In some embodiments, the common source layer 110 may conformally cover the upper surface of the channel layer 134 and the upper surface of the gate insulating layer 132. For example, an upper surface of the gate insulating layer 132 may be located at a lower level than the upper surface of the channel layer 134. Accordingly, a portion of the upper surface and sidewall of the channel layer 134 may be covered by the common source layer 110, and a sufficient contact area between the channel layer 134 and the common source layer 110 may be ensured.

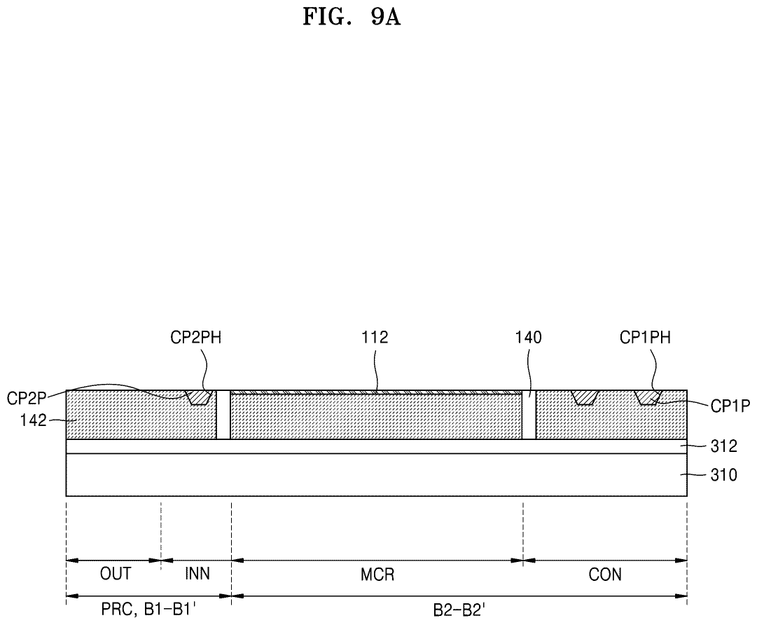

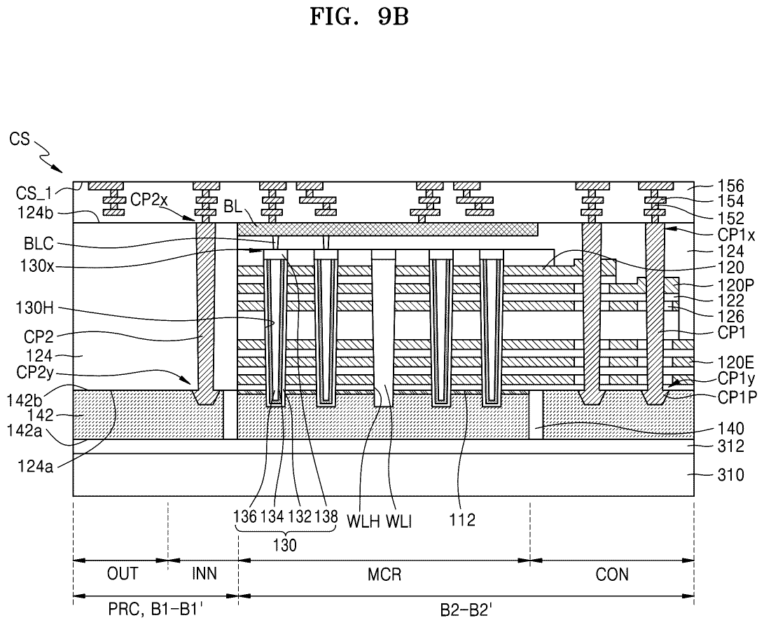

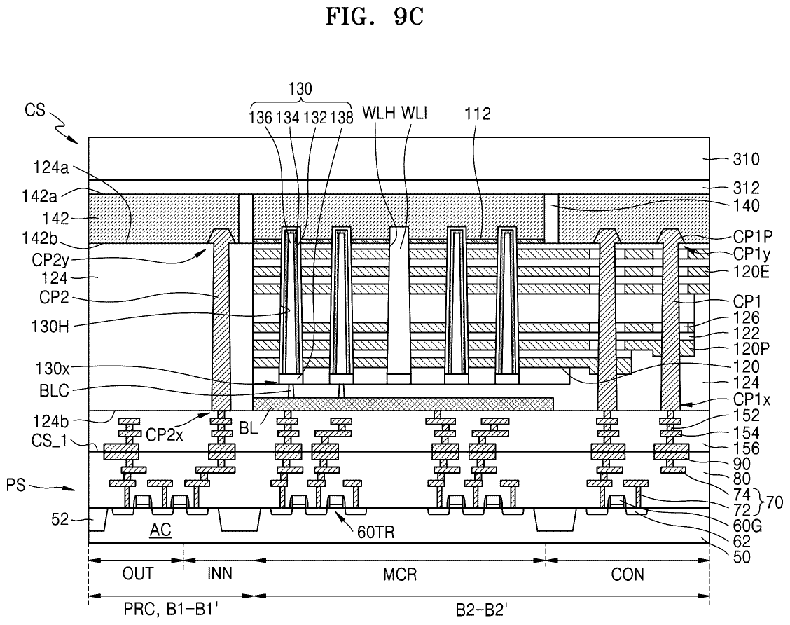

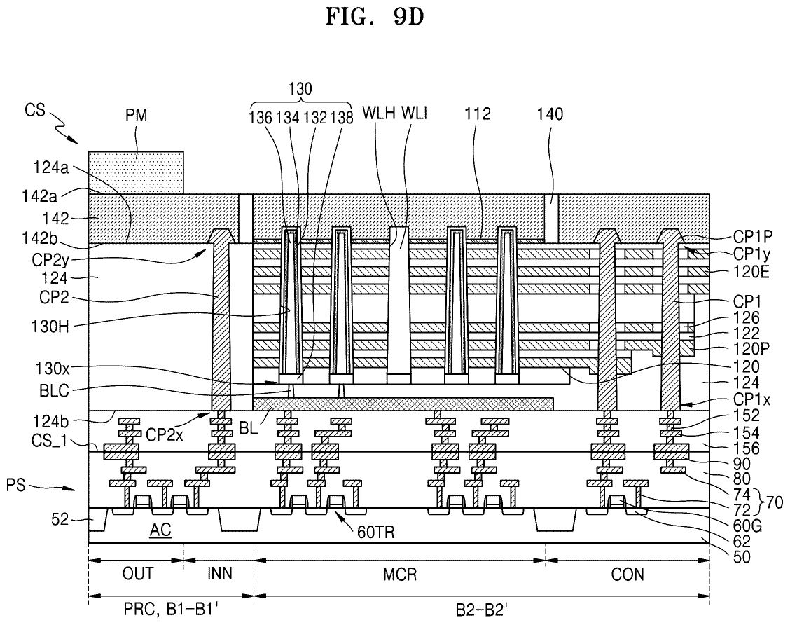

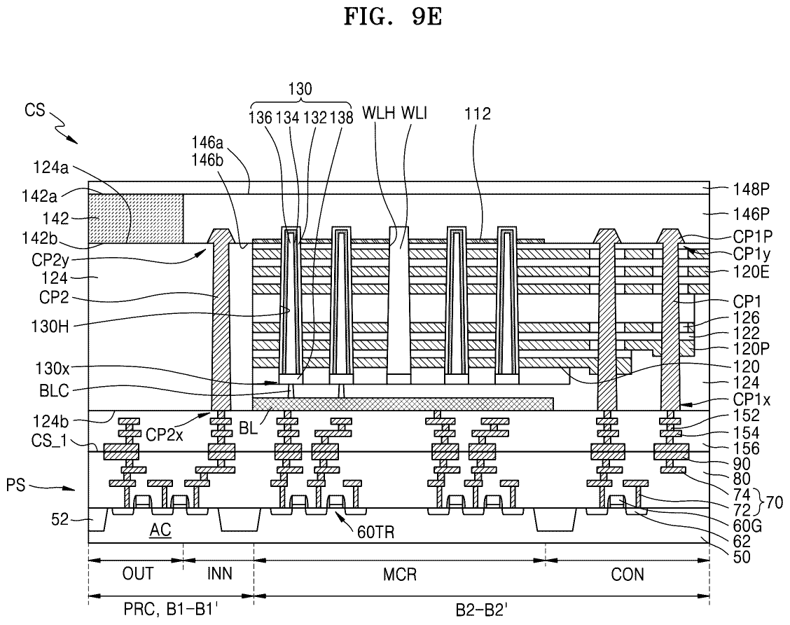

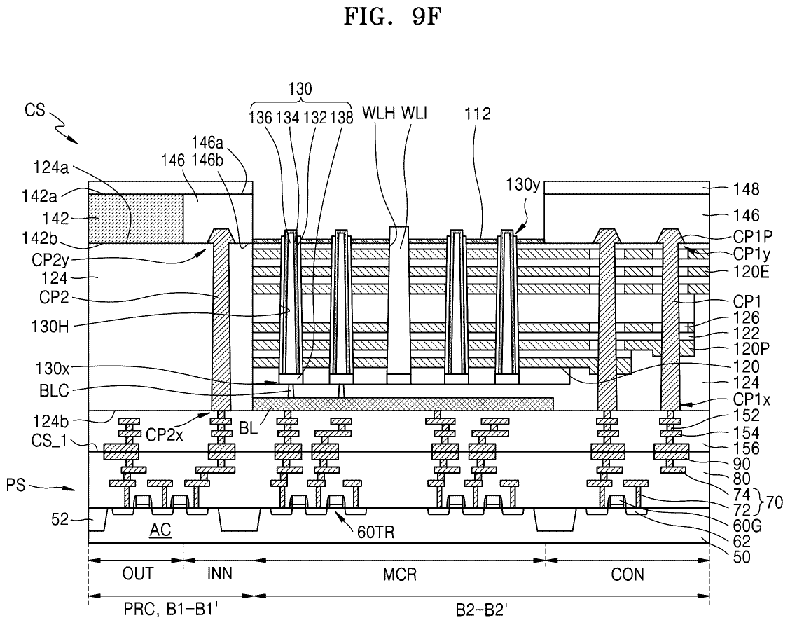

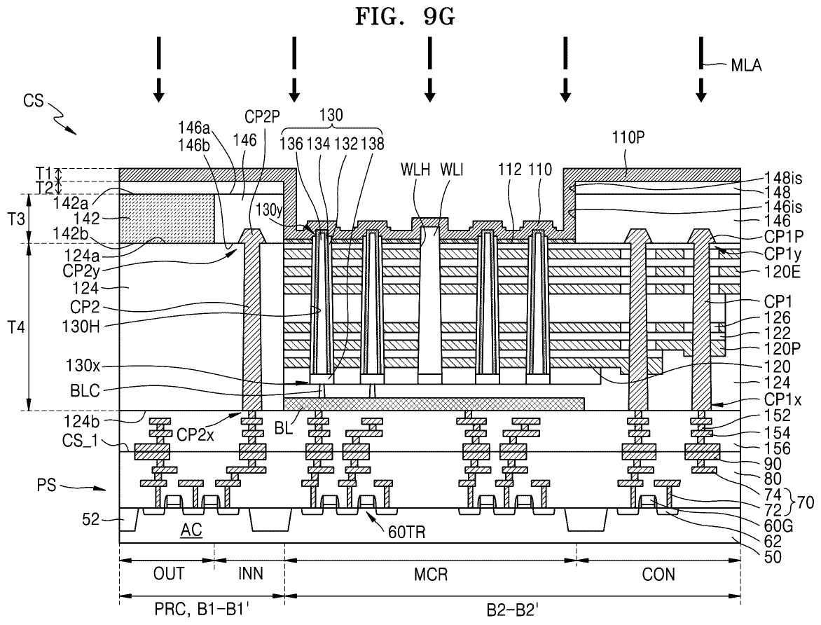

In some embodiments, the common source layer 110 may be formed of or include polysilicon. The common source layer 110 may have a relatively large grain size and/or have relatively high crystalline quality by performing a laser annealing process MLA (refer to FIG. 9G) on the common source layer 110.

In some embodiments, when a laser annealing process MLA (refer to FIG. 9G) is performed on the common source layer 110, the etch stop layer 112 may be crystallized together, and thus the etch stop layer 112 may also have a relatively large grain size and/or may have relatively high crystalline quality. In some embodiments, a physical boundary between the etch stop layer 112 and the common source layer 110 may not be discernible after the laser annealing process MLA (refer to FIG. 9G) is performed.

In the connection region CON and the inner region INN, an upper insulating pattern 146 may be located on the uppermost mold insulating layer 122 of the mold insulating layers 122. In the connection region CON, the upper insulating pattern 146 may cover an upper surface of the uppermost mold insulating layer 122 of the mold insulating layers 122 and a first landing pad CP1P. In the inner region INN, the upper insulating pattern 146 may cover the upper surface 124a of the stack insulating layer 124 and a second landing pad CP2P.

From a plan view, the upper insulating pattern 146 may be located to surround the cell region MCR. An upper surface 146a of the upper insulating pattern 146 may be located at a vertical level higher than the uppermost gate electrode 120. The upper insulating pattern 146 may be formed of or include a silicon oxide film, a silicon nitride film, SiON, SiOCN, SiCN, or a combination thereof.

In the outer region OUT, a conductive base layer 142 may be located on the stack insulating layer 124. A vertical level of an upper surface 142a of the conductive base layer 142 may be substantially the same as a vertical level of the upper surface 146a of the upper insulating pattern 146. A vertical level of a lower surface 142b of the conductive base layer 142 may be substantially the same as a vertical level of a lower surface 146b of the upper insulating pattern 146.

In this specification, the term “substantially the same” may include not only mathematical equality but also a margin of error in the process.

From a plan view, the conductive base layer 142 may be located to surround the upper insulating pattern 146. For example, the conductive base layer 142 may be located above the outer region OUT but may not be located above the inner region INN in which the second plug CP2 is positioned. The boundary between the inner region INN and the outer region OUT may be at a horizontal position substantially the same as a position of the boundary between the upper insulating pattern 146 and the conductive base layer 142.

In embodiments, the conductive base layer 142 may be formed of or include a material with a high absorption coefficient. For example, the absorption coefficient of the conductive base layer 142 may be equal to or greater than 0. In embodiments, the conductive base layer 142 may be formed of or include amorphous silicon, polysilicon, single crystalline silicon, and an amorphous carbon layer (ACL).

When the conductive base layer 142 includes a material with an absorption coefficient equal to or greater than 0, the conductive base layer 142 may effectively absorb laser light output when laser annealing is performed.

In the connection region CON and the peripheral circuit connection region PRC, a cover insulating layer 148 may be located on the upper insulating pattern 146 and the conductive base layer 142. The cover insulating layer 148 may extend from the conductive base layer 142 to the upper insulating pattern 146. The cover insulating layer 148 may be disposed in the entire region of the connection region CON and the peripheral circuit connection region PRC excluding the cell region MCR.

In embodiments, the cover insulating layer 148 may be formed of or include a silicon oxide film, a silicon nitride film, SiON, SiOCN, SiCN, or a combination thereof. In some embodiments, the cover insulating layer 148 may include a reflective layer having a stacked structure of alternately provided silicon oxide films and silicon nitride films.

The common source layer 110 may extend onto an inner wall 146 is of the upper insulating pattern 146. The common source layer 110 may extend onto an inner wall 148 is of the cover insulating layer 148. The common source layer 110 may extend onto an upper surface of the cover insulating layer 148. The common source layer 110 may cover a portion of the upper surface of the cover insulating layer 148. A portion of the common source layer 110, which extends onto the cover insulating layer 148, may be referred to as an edge portion 110P of the common source layer 110.

In the connection region CON, the first plug CP1 formed to pass through the extensions 120E may be located. The first plug CP1 may be formed to pass through any one pad portion 120P of the plurality of gate electrodes 120 and be connected to the pad portion 120P. Insulating patterns 126 may be formed at a position vertically overlapping the pad portion 120P connected to the first plug CP1 and may be formed between the first plug CP1 and the other extensions 120E that correspond to the other pad portions 120P to which the first plug CP1 is not connected.

In embodiments, a third end CP1x of the first plug CP1 may be located adjacent to the peripheral circuit structure PS in the vertical direction Z, and a fourth end CP1y of the first plug CP1 may be located opposite to the third end CP1x in the vertical direction Z. The first plug CP1 may have an inclined sidewall such that a width of the third end CP1x is greater than a width of the fourth end CP1y. The fourth end CP1y of the first plug CP1 may be in contact with the first landing pad CP1P. At least a portion of the first landing pad CP1P may be covered by the upper insulating pattern 146.

Although not shown, in embodiments, the first plug CP1 may include a conductive buried layer and a thin barrier layer surrounding an upper surface and a lateral surface of the conductive buried layer. For example, the conductive buried layer may be formed of or include a metal such as tungsten, nickel, cobalt, or tantalum, metal silicide such as tungsten silicide, nickel silicide, cobalt silicide, or tantalum silicide, doped polysilicon, or a combination thereof. The barrier layer may be formed of or include titanium nitride, tantalum nitride, tungsten nitride, or a combination thereof.

In the inner region INN of the peripheral circuit connection region PRC, the second plug CP2 formed to pass through the stack insulating layer 124 may be located. A fifth end CP2x of the second plug CP2 may be located adjacent to the peripheral circuit structure PS in the vertical direction Z, and a sixth end CP2y of the second plug CP2 may be located opposite to the fifth end CP2x in the vertical direction Z. The second plug CP2 may have an inclined sidewall such that a width of the fifth end CP2x is greater than a width of the sixth end CP2y.

The sixth end CP2y of the second plug CP2 may be in contact with the second landing pad CP2P. At least a portion of the second landing pad CP2P may be covered by the upper insulating pattern 146.

A connection via 152, a connecting wiring layer 154, and a second interlayer insulating layer 156 surrounding the connection via 152 and the connecting wiring layer 154 may be located between the stack insulating layer 124 and the peripheral circuit structure PS. The connection via 152 and the connecting wiring layer 154 may include multiple layers to be located at a plurality of vertical levels, and the bit line BL, the first plug CP1, and the second plug CP2 may be electrically connected to the peripheral circuit structure PS through the connection pad 90 by way of the connection via 152 and the connecting wiring layer 154.

An upper interlayer insulating layer 166 may be disposed on the common source layer 110 and the cover insulating layer 148. A first rear via 170 formed to pass through the upper interlayer insulating layer 166 and the cover insulating layer 148 may be located in the peripheral circuit connection region PRC. A plurality of first rear vias 170 may be provided. The first rear via 170 may extend into the upper insulating pattern 146 and be connected to the second plug CP2. The first rear via 170 may be connected to the second landing pad CP2P. A first rear pad 172 may be disposed on the upper interlayer insulating layer 166. A plurality of first rear pads 172 may be provided. Each of the first rear pads 172 may be connected to any one of the corresponding first rear vias 170.

A second rear via 174 formed to pass through the upper interlayer insulating layer 166 may be located in the cell region MCR. A plurality of second rear vias 174 may be provided. The second rear via 174 may be connected to the common source layer 110. A second rear pad 176 may be connected to the second rear via 174. A plurality of second rear pads 176 may be provided. A passivation layer 180 may be disposed on the upper interlayer insulating layer 166, and an opening of the passivation layer 180 may expose the upper surface of the second rear pad 176 therethrough.

The edge portion 110P of the common source layer 110 may have a first thickness T1. The cover insulating layer 148 may have a second thickness T2. The conductive base layer 142 may have a third thickness T3. The third thickness T3 may be substantially the same as a thickness of the upper insulating pattern 146. The stack insulating layer 124 may have a fourth thickness T4. All of the first to fourth thicknesses T1 to T4 may mean thicknesses in the vertical direction Z.

The first thickness T1 may be about 30 nm to about 70 nm. When the first thickness T1 is less than 30 nm, the electrical resistance of the common source layer 110 may increase. The second thickness T2 may be about 1 nm but less than about 1 μm.

The third thickness T3 may be a value y₁ (y₁ is a positive number) that satisfies Equation 1 below.

$${x}_{1} - 30 nm \leq {y}_{1} \leq {x}_{1} + 30 nm \qquad Equation 1$$

x₁ may be a value that satisfies Equation 2 below.

$$\frac{λ}{4} * 2 ( \frac{{x}_{1}}{( \frac{λ}{4 {x}_{1}} )} ) = \frac{2 n}{2} * λ , \\ where n is an integer equal to or greater than 1. \qquad Equation 2$$

In Equation 2 above, λ may be a wavelength of laser light when laser annealing is performed on the common source layer 110. In an embodiment, the laser light may be visible light. For example, λ may be about 300 nm to about 700 nm.

For example, the fourth thickness T4 may be a distance from a lower surface of the bit line BL to an upper surface of the uppermost mold insulating layer 122. For example, the fourth thickness T4 may be greater than the second thickness T2. For example, the fourth thickness T4 may be about 15 μm to 30 μm. For example, the fourth thickness T4 may be about 18 μm to about 26 μm.

Generally, in a structure in which the peripheral circuit structure PS and the cell structure CS are bonded to each other using a bonding method, the common source layer 110 is formed at an upper portion of the cell structure CS via deposition, and a laser annealing process MLA (refer to FIG. 9G) may be performed to promote crystallization. Due to the configuration of the channel structure 130, the gate electrodes 120, and the first plug CP1, the connection via 152 and the connecting wiring layer 154 may be less affected by the laser annealing process MLA (refer to FIG. 9G) in the cell region MCR and the connection region CON than in the peripheral circuit connection region PRC. In the inner region INN of the peripheral circuit connection region PRC, the connection via 152 and the connecting wiring layer 154 may be less affected by the laser annealing process MLA (refer to FIG. 9G) due to the second plug CP2.

However, the connection via 152 and the connecting wiring layer 154 formed in the outer region OUT of the peripheral circuit connection region PRC may be adversely affected by the laser annealing process MLA (refer to FIG. 9G). The adverse effect may be due to the fact that a structure to protect the connection via 152 and the connecting wiring layer 154 from laser light is not located in the outer region OUT.

The semiconductor device 100 according to embodiments may include the cell structure CS including the stack insulating layer 124, the conductive base layer 142, and the cover insulating layer 148 sequentially stacked in the outer region OUT. In the inner region INN, the edge portion 110P of the common source layer 110 may be located. The edge portion 110P of the common source layer 110 may have the first thickness T1. The first thickness T1 may be about 30 nm to about 70 nm. The cover insulating layer 148 may have the second thickness T2. The second thickness T2 may be about 1 nm but less than about 1 μm. The conductive base layer 142 may have the third thickness T3. The third thickness T3 may be a y₁ value that satisfies Equation 1 described above. The fourth thickness T4 may be about 15 μm to about 30 μm.

When the first to fourth thicknesses T1 to T4 each have the above range, the amount of laser light reaching the connection via 152 and the connecting wiring layer 154 may be minimized when laser annealing is performed. The range may correspond to a condition in which constructive interference occurs between laser lights reflected from each of an upper surface of the edge portion 110P of the common source layer 110, an upper surface of the cover insulating layer 148, the upper surface 142a of the conductive base layer 142, and the upper surface 124a of the stack insulating layer 124. In this case, the amount of laser light transmitted through the connection via 152 and the connecting wiring layer 154 may be minimized. For the same reason, the amount of laser light transmitted to the peripheral circuit wiring structure 70 may be minimized. For the above reasons, the electrical characteristics and reliability of the semiconductor device 100 may be improved.

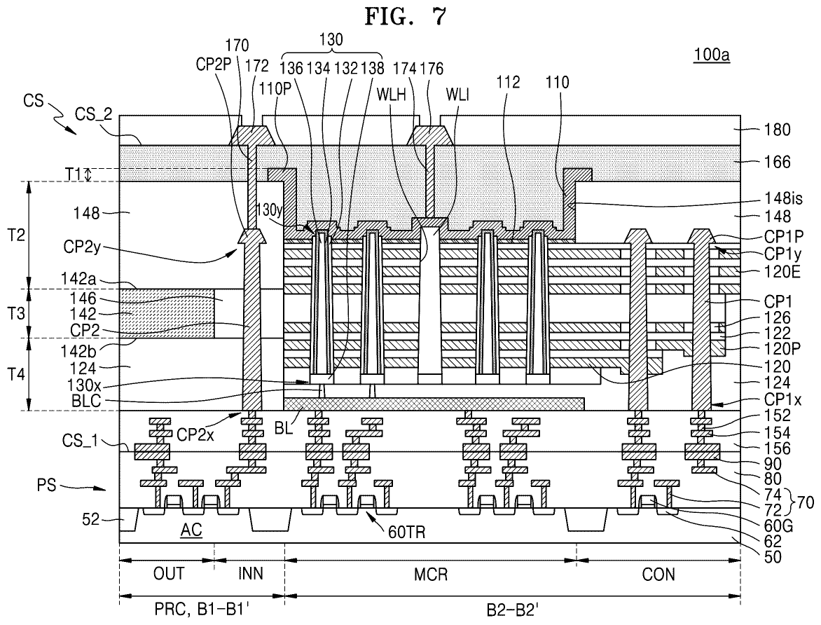

FIG. 7 is a cross-sectional view taken along lines B1-B1′ and B2-B2′ of FIG. 5. Hereinafter, repeated descriptions of FIGS. 4 to 6 are omitted or explained briefly, and differences alone are described in detail.

Referring to FIG. 7, a semiconductor device 100a may include the peripheral circuit structure PS and the cell structure CS on the peripheral circuit structure PS. The cell structure CS may include the stack insulating layer 124, the conductive base layer 142, the upper insulating pattern 146, and the cover insulating layer 148.

In the peripheral circuit connection region PRC of the cell structure CS, a vertical level of the upper surface 124a of the stack insulating layer 124 may be lower than a vertical level of an upper surface of the uppermost mold insulating layer 122. In the peripheral circuit connection region PRC, a vertical level of the upper surface 124a of the stack insulating layer 124 may be lower than a vertical level of the sixth end CP2y of the second plug CP2.

The upper insulating pattern 146 may be located in the inner region INN alone (e.g., without being in the outer region OUT). In the inner region INN, the upper insulating pattern 146 may be located on the stack insulating layer 124. In the inner region INN, a vertical level of the upper surface 146a of the upper insulating pattern 146 may be lower than a vertical level of an upper surface of the uppermost mold insulating layer 122. In the inner region INN, a vertical level of the lower surface 146b of the upper insulating pattern 146 may be the same as a vertical level of upper surface 124a of the stack insulating layer 124.

In the outer region OUT, the conductive base layer 142 may be located on the stack insulating layer 124. The conductive base layer 142 may surround the upper insulating pattern 146. In the outer region OUT, a vertical level of the upper surface 142a of the conductive base layer 142 may be lower than a vertical level of an upper surface of the uppermost mold insulating layer 122. In the outer region OUT, a vertical level of the lower surface 142b of the conductive base layer 142 may be the same as a vertical level of upper surface 124a of the stack insulating layer 124.

In the peripheral circuit connection region PRC, the cover insulating layer 148 may be disposed on the conductive base layer 142 and the upper insulating pattern 146. In the peripheral circuit connection region PRC, the cover insulating layer 148 may cover the upper surface 142a of the conductive base layer 142 and the upper surface 146a the upper insulating pattern 146. In the peripheral circuit connection region PRC, a vertical level of a lower surface of the cover insulating layer 148 may be lower than a vertical level of an upper surface of the uppermost mold insulating layer 122.

In the inner region INN, the second plug CP2 may be formed to pass through the stack insulating layer 124 and the upper insulating pattern 146. In the inner region INN, the second plug CP2 may extend upwards into the cover insulating layer 148 in the vertical direction Z. In the inner region INN, the second plug CP2 may be at least partially surrounded by the cover insulating layer 148.

The edge portion 110P of the common source layer 110 may have the first thickness T1. The description of the first thickness T1 may be the same as the description of the first thickness T1 in FIG. 6.

In the peripheral circuit connection region PRC, the cover insulating layer 148 may have the second thickness T2. For example, the second thickness T2 may be about 15 μm to 30 μm. For example, the second thickness T2 may be about 18 μm to about 26 μm.

The conductive base layer 142 may have the third thickness T3. The third thickness T3 may be substantially the same as the thickness of the upper insulating pattern 146. The third thickness T3 may be a value y₂ (y₂ is a positive number) that satisfies Equation 3 below.

x₂−30 nm≤y₂≤x₂+30 nm Equation 3

x₂ may be a value that satisfies Equation 4 below.

$$\frac{λ}{4} * 2 ( \frac{{x}_{2}}{( \frac{λ}{4 {x}_{2}} )} ) = \frac{2 n - 1}{2} * λ , \\ where n is an integer equal to or greater than 1. \qquad Equation 4$$

In Equation 4 above, κ may be a wavelength of laser light when laser annealing is performed on the common source layer 110. In an embodiment, the laser light may be visible light. For example, λ may be about 300 nm to about 700 nm.

In the peripheral circuit connection region PRC, the stack insulating layer 124 may have the fourth thickness T4. For example, the fourth thickness T4 may be a distance from the lower surface 124b to the upper surface 124a of the stack insulating layer 124. For example, the fourth thickness T4 may be less than the second thickness T2. The fourth thickness T4 may be about 1 nm but less than about 1 μm.

Similar to the description in FIG. 6, in FIG. 7, when the first to fourth thicknesses T1 to T4 each have the above range, the amount of laser light reaching the connection via 152 and the connecting wiring layer 154 when laser annealing is performed may be minimized. For the same reason, the amount of laser light transmitted to the peripheral circuit wiring structure 70 may be minimized. Accordingly, the electrical characteristics and reliability of the semiconductor device 100a may be improved.

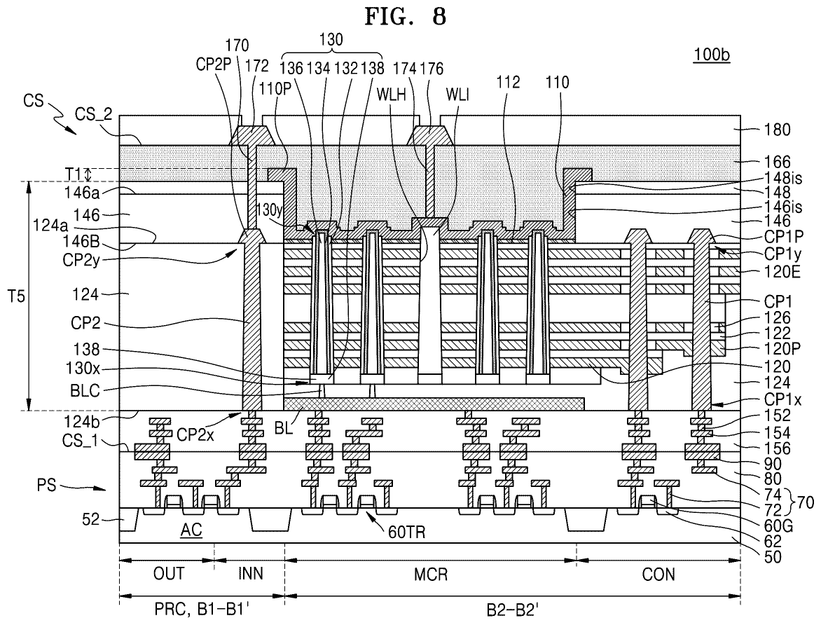

FIG. 8 is a cross-sectional view taken along lines B1-B1′ and B2-B2′ of FIG. 5. Hereinafter, repeated descriptions of FIGS. 4 to 6 will be omitted or explained briefly, and differences alone are described in detail.

Referring to FIG. 8, a semiconductor device 100b may include a peripheral circuit structure PS and a cell structure CS on the peripheral circuit structure PS. The cell structure CS may include the stack insulating layer 124, the upper insulating pattern 146, and the cover insulating layer 148.

The cell structure CS may not include the conductive base layer 142 shown in FIG. 6. Instead, a space in which the conductive base layer 142 shown in FIG. 6 is located may be filled with the upper insulating pattern 146. The upper insulating pattern 146 may extend from the connection region CON to the peripheral circuit connection region PRC. The upper insulating pattern 146 may extend from the inner region INN to the outer region OUT. The cover insulating layer 148 may cover the upper surface 146a of the upper insulating pattern 146.

The edge portion 110P of the common source layer 110 may have the first thickness T1. A vertical distance from the lower surface 124b of the stack insulating layer 124 to the upper surface of the cover insulating layer 148 may be the fifth thickness T5. The second to fourth thicknesses T2 to T4 shown in FIG. 6 are omitted.

The first thickness T1 may be a value y₃ (y₃ is a positive number) that satisfies Equation 5 below.

$${x}_{3} - 5 nm \leq {y}_{3} \leq {x}_{3} + 5 nm \qquad Equation 5$$

x₃ may be a value that satisfies Equation 6 below.

$$\frac{λ}{4} * 2 ( \frac{{x}_{3}}{( \frac{λ}{4 {x}_{3}} )} ) = \frac{2 n - 1}{2} * λ , \\ where n is an integer equal to or greater than 1. \qquad Equation 6$$

In Equation 4 above, λ may be a wavelength of laser light when laser annealing is performed on the common source layer 110. In an embodiment, the laser light may be visible light. For example, λ may be about 300 nm to about 700 nm.

For example, the first thickness T1 may be about 70 nm to about 200 nm.

For example, the fifth thickness T5 may be about 15 μm to about 30 μm. For example, the fifth thickness T5 may be about 18 μm to about 26 μm.

Equation 5 and Equation 6 may be equally applied to the first thickness T1 of the edge portion 110P of the common source layer 110 in FIGS. 6 and 7.

When the first thickness T1 is about 70 nm to about 200 nm, the conductive base layer 142 shown in FIG. 6 may be omitted. As shown, e.g., in FIG. 9G, at a step in the manufacturing process when laser annealing MLA is performed, the edge portion 110P of the common source layer 110 extends above both the inner region INN and the outer region OUT. When the first thickness T1 is about 30 nm to about 70 nm as shown in FIG. 6, it is difficult to cause constructive interference of light reflected from the upper surface of the edge portion 110P of the common source layer 110 and light reflected from the upper surface of the cover insulating layer 148. On the other hand, when the first thickness T1 is about 70 nm to about 200 nm, it may cause constructive interference of light reflected from the upper surface of the edge portion 110P of the common source layer 110 and light reflected from the upper surface of the cover insulating layer 148. Accordingly, when laser annealing is performed on the common source layer 110, laser light may not reach the connection via 152 and the connecting wiring layer 154. For the same reason, the amount of laser light transmitted to the peripheral circuit wiring structure 70 may be minimized. For the above reasons, the electrical characteristics and reliability of the semiconductor device 100b may be improved.

FIGS. 9A to 9G are schematic diagrams showing a method of manufacturing a semiconductor device according to embodiments and are cross-sectional views taken along lines B1-B1′ and B2-B2′ of FIG. 5.

Referring to FIG. 9A, a buffer insulating layer 312 may be formed on a carrier substrate 310, and the conductive base layer 142 may be formed on the buffer insulating layer 312.

In embodiments, the carrier substrate 310 may be formed of or include silicon (Si), germanium (Ge), silicon germanium (SiGe), gallium arsenide (GaAs), indium gallium arsenide (InGaAs), aluminum gallium arsenide (AlGaAs), or mixtures thereof. The buffer insulating layer 312 may be formed using a combination of silicon oxide, a double layer of silicon oxide and titanium nitride, and a double layer of silicon oxide and silicon nitride.

In embodiments, the conductive base layer 142 may include a material with a large absorption coefficient. For example, the absorption coefficient of the conductive base layer 142 may be equal to or greater than 0. In embodiments, the conductive base layer 142 may be formed of or include amorphous silicon, polysilicon, single crystalline silicon, and an ACL.

On the carrier substrate 310, the cell region MCR, the connection region CON, and the peripheral circuit connection region PRC may be defined, and the conductive base layer 142 may be formed at a uniform height over the entire area of the cell region MCR, the connection region CON, and the peripheral circuit connection region PRC. The peripheral circuit connection region PRC may include the inner region INN and the outer region OUT surrounding the inner region INN.

An insulating wall 140 may be formed by removing a portion of the conductive base layer 142. The insulating wall 140 may be formed at a boundary of the cell region MCR and the connection region CON, at a boundary of the cell region MCR and the peripheral circuit connection region PRC, and/or at a boundary of the connection region CON and the peripheral circuit connection region PRC.

A first landing pad opening CP1PH may be formed by removing a portion of the conductive base layer 142 in the connection region CON, and the first landing pad CP1P may be formed within the first landing pad opening CP1PH. A second landing pad opening CP2PH may be formed by removing a portion of the conductive base layer 142 in the inner region INN, and the second landing pad CP2P may be formed within the second landing pad opening CP2PH.

Then, the etch stop layer 112 may be formed on the conductive base layer 142 in the cell region MCR. In embodiments, the etch stop layer 112 may be formed using polysilicon.

Referring to FIG. 9B, gate electrodes 120 and mold insulating layers 122 may be formed in the cell region MCR and the connection region CON, and the extensions 120E and the pad portion 120P connected to the gate electrodes 120 may be formed in the connection region CON. In the cell region MCR, the channel structure 130 passing through the gate electrodes 120 to extend in the vertical direction Z, and the bit line BL connected to the channel structure 130 may be formed. Referring to FIGS. 5 and 9B together, the stack separation opening WLH extending in the first horizontal direction X from the cell region MCR to the connection region CON may be formed. The stack separation insulating layer WLI may be formed in the stack separation opening WLH.

The first plug CP1 may be formed to pass through the extensions 120E and the pad portion 120P in the connection region CON, and the second plug CP2 may be formed to pass through the stack insulating layer 124 in the inner region INN. The connection via 152, the connecting wiring layer 154, and the second interlayer insulating layer 156 that are electrically connected to the bit line BL, the first plug CP1, and the second plug CP2 may be formed.

In embodiments, in a process for forming the channel structure 130, the first end 130x of the channel structure 130 may be located at a higher vertical level than the second end 130y. The second end 130y of the channel structure 130 may be formed to pass through the etch stop layer 112 and extend into the conductive base layer 142. For example, the second end 130y of the channel structure 130 may be located at a lower vertical level than the upper surface 142a of the conductive base layer 142.

In embodiments, in a process of forming the first plug CP1, the third end CP1x of the first plug CP1 may be formed to have a larger width than the fourth end CP1y. The fourth end CP1y of the first plug CP1 may be connected to the first landing pad CP1P.

In embodiments, in a process of forming the second plug CP2, the fifth end CP2x of the second plug CP2 may be formed to have a larger width than the sixth end CP2y. The sixth end CP2y of the second plug CP2 may be connected to the second landing pad CP2P.

The connection via 152, the connecting wiring layer 154, and the second interlayer insulating layer 156 surrounding the connection via 152 and the connecting wiring layer 154 may be formed on the stack insulating layer 124.

Referring to FIG. 9C, the peripheral circuit structure PS may be prepared. The peripheral circuit structure PS may include the peripheral circuit transistor 60TR and the peripheral circuit wiring structure 70 that are located on the substrate 50. The active region AC may be defined by the device separation layer 52 on the substrate 50, and the plurality of peripheral circuit transistors 60TR may be formed on the active region AC. The plurality of peripheral circuit transistors 60TR may include the peripheral circuit gate 60G and the source/drain regions 62 located on each side of the substrate 50 of the peripheral circuit gate 60G.

Then, the peripheral circuit structure PS may be attached to the cell structure CS. The peripheral circuit structure PS and the cell structure CS may be attached to each other through the connection pad 90 and the first and second interlayer insulating layers 80 and 156 by using a metal-oxide hybrid bonding method, but the inventive concept is not limited thereto.

Then, a structure in which the peripheral circuit structure PS and the cell structure CS are attached to each other may be turned over such that the carrier substrate 310 faces upward.

Referring to FIG. 9D, the carrier substrate 310 (refer to FIG. 9C) may be removed. The carrier substrate 310 may be removed by a grinding process and a subsequent etching process, and the buffer insulating layer 312 (refer to FIG. 9C) may be exposed.

Then, the buffer insulating layer 312 (refer to FIG. 9C) may also be removed and the upper surface 142a of the conductive base layer 142 and the upper surface of the insulating wall 140 may be exposed. Here, the upper surface 142a of the conductive base layer 142 may refer to a surface of the conductive base layer 142 in contact with the buffer insulating layer 312, and a bottom surface of the conductive base layer 142 may refer to a surface of the conductive base layer 142 located adjacent to the channel structure 130.

In the outer region OUT of the peripheral circuit connection region PRC, a mask pattern PM may be formed on the conductive base layer 142. The mask pattern PM may expose the upper surface 142a of the conductive base layer 142 in the cell region MCR, the connection region CON, and the inner region INN.

Referring to FIG. 9E, an etching process may be performed using the mask pattern PM (refer to FIG. 9D) as an etch mask. Due to the etching process, a portion of the conductive base layer 142, which is located in the cell region MCR, the connection region CON, and the inner region INN, may be removed. As the conductive base layer 142 is removed, the second end 130y of the channel structure 130, an upper portion of the stack separation insulating layer WLI, the first landing pad CP1P, and the second landing pad CP2P may be exposed.

Subsequently, an upper insulating layer 146P may be formed to cover the second end 130y of the channel structure 130, the upper portion of the stack separation insulating layer WLI, the first landing pad CP1P, and the second landing pad CP2P, which are exposed. The upper insulating layer 146P may be formed of or include a silicon oxide film, a silicon nitride film, SiON, SiOCN, SiCN, or a combination thereof.

Subsequently, a cover insulating layer 148P may be formed on the upper insulating layer 146P. The cover insulating layer 148P may be formed of or include a silicon oxide film, a silicon nitride film, SiON, SiOCN, SiCN, or a combination thereof. In some embodiments, the cover insulating layer 148P may include a reflective layer having a stacked structure in which silicon oxide films and silicon nitride films are alternatively located.

Referring to FIG. 9F, an etching process may be performed on the upper insulating layer 146P and the cover insulating layer 148P of FIG. 9E. A portion of the upper insulating layer 146P and a portion of the cover insulating layer 148P may be removed through an etching process. Through an etching process, the upper insulating pattern 146 may be formed from the upper insulating layer 146P, and the cover insulating layer 148 may be formed from the cover insulating layer 148P. Through the etching process, the inner wall 146 is of the upper insulating pattern 146 may be exposed and the inner wall 148 is of the cover insulating layer 148 may be exposed.

As a portion of the upper insulating layer 146P and a portion of the cover insulating layer 148P are removed, the second end 130y of the channel structure 130 may be exposed.

Then, a portion of the gate insulating layer 132, which is exposed at the second end 130y of the channel structure 130, may be removed to expose the upper surface of the channel layer 134. A removal process of the gate insulating layer 132 may be performed until the upper surface of the etch stop layer 112 is exposed in the removal process of the gate insulating layer 132. In some embodiments, the gate insulating layer 132 may be located at a lower level than the upper surface of the channel layer 134, and an upper portion of the gate insulating layer 132 may be further removed to expose a portion of the upper surface and sidewall of the channel layer 134.

During the removal process of the gate insulating layer 132, an upper side of the stack separation insulating layer WLI may also be exposed and protrude to an upper side of the etch stop layer 112.

Referring to FIG. 9G, the common source layer 110 may be formed on the cell region MCR, the connection region CON, and the peripheral circuit connection region PRC. The common source layer 110 may be formed using a polysilicon. For example, the common source layer 110 may be formed using polysilicon doped with n-type impurities.

In the cell region MCR, the common source layer 110 may be conformally formed on the exposed upper surfaces of the etch stop layer 112 and the channel layer 134. The common source layer 110 may extend onto the cover insulating layer 148. As the common source layer 110 is formed on the relatively flat upper surface of the cover insulating layer 148 in the connection region CON and the peripheral circuit connection region PRC, the common source layer 110 may be formed to have a relatively flat upper level.

The edge portion 110P of the common source layer 110 may be a portion of the common source layer 110 extending onto the cover insulating layer 148.

The edge portion 110P of the common source layer 110 may have the first thickness T1. The cover insulating layer 148 may have the second thickness T2. The conductive base layer 142 may have the third thickness T3. The stack insulating layer 124 may have the fourth thickness T4. The description of the first to fourth thicknesses T1 to T4 may be the same as the description of the first to fourth thicknesses T1 to T4 described in FIG. 6.

The laser annealing process MLA may be performed on the common source layer 110. In embodiments, the laser annealing process MLA may be performed to improve a crystallization degree of the common source layer 110 located in the cell region MCR, increase a grain size of the common source layer 110, or reduce the resistance of the common source layer 110. In some embodiments, a physical boundary between the etch stop layer 112 and the common source layer 110 may not be discernible after the laser annealing process MLA (refer to FIG. 9G) is performed.

When the laser annealing process MLA is performed on the common source layer 110, each of the first to fourth thicknesses T1 to T4 may have a certain range as described in FIG. 6, and thus it may be possible to prevent heat generated by laser light from being transmitted to the connection via 152 and the connecting wiring layer 154 that are located in the outer region OUT of the peripheral circuit connection region PRC.

When the laser annealing process MLA is performed on the common source layer 110, laser light in a visible light band may be used. The wavelength of laser light may range from about 300 nm to about 700 nm.

Referring back to FIG. 6, a portion of the common source layer 110, which is located in the connection region CON and the peripheral circuit connection region PRC, may be removed. In embodiments, the common source layer 110 is formed on a relatively flat upper surface of the cover insulating layer 148 in the connection region CON and the peripheral circuit connection region PRC, and thus the difficulty of the process to remove the common source layer 110 may be reduced.

In some embodiments, the edge portion 110P of the common source layer 110 may extend onto the inner wall 146 is of the upper insulating pattern 146 and onto the inner wall 148 is of the cover insulating layer 148. The edge portion 110P of the common source layer 110 may further extend to the upper surface of the cover insulating layer 148. Accordingly, a vertical level difference may be generated between a central portion of the common source layer 110 and the edge portion 110P of the common source layer 110.

Referring to FIG. 6, the upper interlayer insulating layer 166 may be located on the common source layer 110 and the cover insulating layer 148. Then, the first rear via 170 formed to pass through the upper interlayer insulating layer 166 and the cover insulating layer 148 may be located in the inner region INN. The first rear via 170 may extend into the upper insulating pattern 146. The first rear via 170 may be connected to the second landing pad CP2P. The second rear via 174 formed to pass through the upper interlayer insulating layer 166 may be formed in the cell region MCR. The second rear via 174 may be connected to the common source layer 110.

On the upper interlayer insulating layer 166, the first rear pad 172 connected to the first rear via 170 may be formed, and the second rear pad 176 connected to the second rear via 174 may be formed. Then, the passivation layer 180 covering the first and second rear pads 172 and 176 may be formed on the upper interlayer insulating layer 166, and an opening may be formed to expose upper surfaces of the first and second rear pads 172 and 176 on the passivation layer 180.

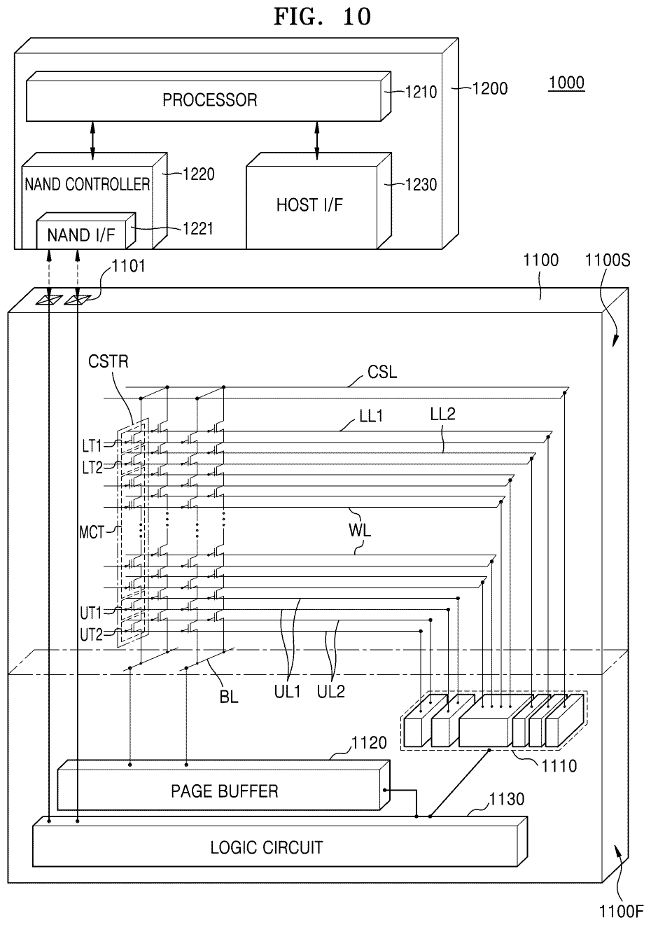

FIG. 10 is a schematic diagram showing a data storage system 1000 including a semiconductor device according to embodiments.

Referring to FIG. 10, the data storage system 1000 may include one or more semiconductor devices 1100 and a memory controller 1200 electrically connected to the semiconductor device 1100. The data storage system 1000 may be, for example, solid state drive device (SSD), universal serial bus (USB), a computing system, a medical device, or a communication device including at least one semiconductor device 1100.

The semiconductor device 1100 may be a non-volatile semiconductor device, and for example, the semiconductor device 1100 may be a NAND FLASH semiconductor device including one of the semiconductor devices 10, 100, 100a, and 100b described with reference to FIGS. 1 to 8. The semiconductor device 1100 may include a first structure 1100F and a second structure 1100S on the first structure 1100F. The first structure 1100F may be a peripheral circuit structure PS (in FIG. 3) including a row decoder 1110, a page buffer 1120, and a logic circuit 1130.

The second structure 1100S may be the memory cell structure CS (in FIG. 3) including the bit line BL, the common source line CSL, the plurality of word lines WL, first and second string selection lines UL1 and UL2, first and second ground selection lines LL1 and LL2, and a plurality of memory cell strings CSTR between the bit line BL and the common source line CSL.

In the second structure 1100S, the plurality of memory cell strings CSTR may include ground selection transistors LT1 and LT2 adjacent to the common source line CSL, string selection transistors UT1 and UT2 adjacent to the bit line BL, and a plurality of memory cell transistors MCT located between the ground selection transistors LT1 and LT2 and the string selection transistors UT1 and UT2. The number of the ground selection transistors LT1 and LT2 and the number of string selection transistors UT1 and UT2 may be varied in various ways, depending on embodiments.

In embodiments, the plurality of ground selection lines LL1 and LL2 may be connected to gate electrodes of the ground selection transistors LT1 and LT2, respectively. The word line WL may be connected to a gate electrode of the memory cell transistor MCT. The plurality of string selection lines UL1 and UL2 may be connected to gate electrodes of the string selection transistors UT1 and UT2, respectively.

The common source line CSL, the plurality of ground selection lines LL1 and LL2, the plurality of word lines WL, and the plurality of string selection lines UL1 and UL2 may be connected to the row decoder 1110. The plurality of bit lines BL may be electrically connected to the page buffer 1120.

The semiconductor device 1100 may communicate with the memory controller 1200 through an input/output pad 1101 that is electrically connected to the logic circuit 1130

The memory controller 1200 may include a processor 1210, a NAND controller 1220, and a host interface 1230. In some embodiments, the data storage system 1000 may include the plurality of semiconductor devices 1100, and in this case, the memory controller 1200 may control the plurality of semiconductor devices 1100.

The processor 1210 may control the overall operation of the data storage system 1000, including the memory controller 1200. The processor 1210 may operate according to certain firmware and may control the NAND controller 1220 to access the semiconductor device 1100. The NAND controller 1220 may include a NAND interface 1221 that processes communication with the semiconductor device 1100. Through the NAND interface 1221, a control command for controlling the semiconductor device 1100, data to be written in the plurality of memory cell transistors MCTs of the semiconductor device 1100, and data to be read from the plurality of memory cell transistors MCT of the semiconductor device 1100 may be transmitted. The host interface 1230 may provide a communication function between the data storage system 1000 and an external host. When receiving a control command from the external host through the host interface 1230, the processor 1210 may control the semiconductor device 1100 in response to the control command.

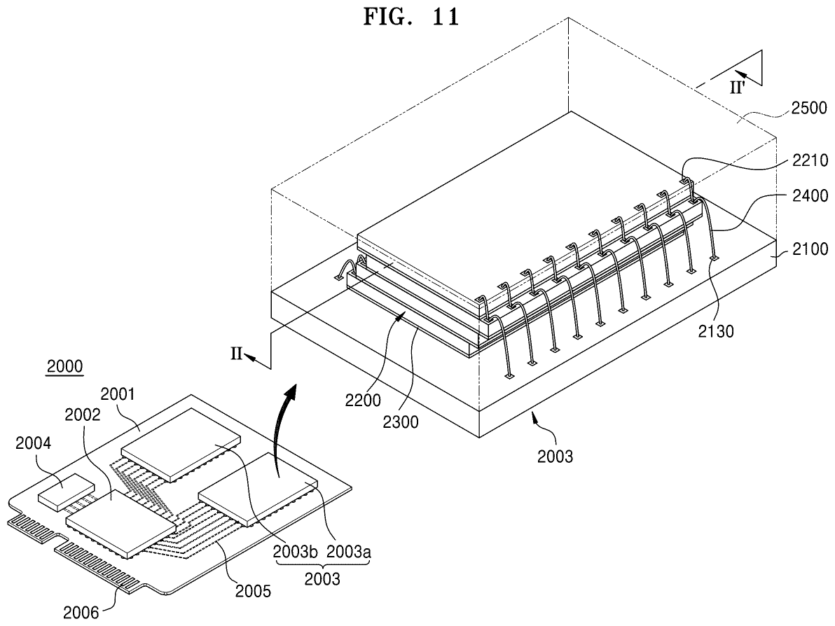

FIG. 11 is a schematic perspective diagram showing a data storage system including a semiconductor device according to embodiments.

Referring to FIG. 11, a data storage system 2000 according to an embodiment may include a main substrate 2001, a memory controller 2002 mounted on the main substrate 2001, one or more semiconductor packages 2003, and a DRAM 2004. The semiconductor package 2003 and the DRAM 2004 may be connected to the memory controller 2002 through a plurality of wiring patterns 2005 formed on the main substrate 2001.

The main substrate 2001 may include a connector 2006 including a plurality of pins coupled to the external host. The number and arrangement of the plurality of pins in the connector 2006 may vary depending on a communication interface between the data storage system 2000 and the external host. In embodiments, the data storage system 2000 may communicate with the external host by using any one of interfaces including universal serial bus (USB), peripheral component interconnect express (PCI-Express), serial advanced technology attachment (SATA), and M-Phy for universal flash storage (UFS). In embodiments, the data storage system 2000 may operate using power supplied from the external host through the connector 2006. The data storage system 2000 may further include a power management integrated circuit (PMIC) that distributes power supplied from the external host to the memory controller 2002 and the semiconductor package 2003.

The memory controller 2002 may write data to or read data from the semiconductor package 2003, and may improve an operating speed of the data storage system 2000.

The DRAM 2004 may be a buffer memory to alleviate a speed difference between the semiconductor package 2003, which is a data storage space, and the external host. The DRAM 2004 included in the data storage system 2000 may operate as a type of cache memory and may provide a space for temporarily storing data during a control operation for the semiconductor package 2003. When the DRAM 2004 is included in the data storage system 2000, the memory controller 2002 may further include a DRAM controller for controlling the DRAM 2004 in addition to the NAND controller for controlling the semiconductor package 2003.

The semiconductor package 2003 may include first and second semiconductor packages 2003a and 2003b that are apart from each other. The first and second semiconductor packages 2003a and 2003b may each be a semiconductor package include a plurality of semiconductor chips 2200. Each of the first and second semiconductor packages 2003a and 2003b may include a package substrate 2100, the plurality of semiconductor chips 2200 on the package substrate 2100, an adhesive layer 2300 located on a lower surface of each of the plurality of semiconductor chips 2200, a connection structure 2400 electrically connecting the plurality of semiconductor chips 2200 to the package substrate 2100, and a molding layer 2500 covering the plurality of semiconductor chips 2200 and the connection structure 2400 on the package substrate 2100.

The package substrate 2100 may be a printed circuit board including a plurality of package upper pads 2130. Each of the plurality of semiconductor chips 2200 may include an input/output pad 2210. The input/output pad 2210 may correspond to the input/output pad 1101 of FIG. 10. Each of the plurality of semiconductor chips 2200 may include at least one of the semiconductor devices 10, 100, 100a, and 100b described with reference to FIGS. 1 to 8.

In embodiments, the connection structure 2400 may be a bonding wire that electrically connects the input/output pad 2210 to a package upper pad 2130. Accordingly, in the first and second semiconductor packages 2003a and 2003b, the plurality of semiconductor chips 2200 may be electrically connected to each other using a bonding wire method and may be electrically connected to the package upper pad 2130 of the package substrate 2100. In embodiments, in the first and second semiconductor packages 2003a and 2003b, the plurality of semiconductor chips 2200 may be electrically connected to each other by a connection structure including a through silicon via (TSV) instead of a bonding wire connection structure 2400.

In embodiments, the memory controller 2002 and the plurality of semiconductor chips 2200 may be included in one package. In an embodiment, the memory controller 2002 and the plurality of semiconductor chips 2200 may be mounted on a separate interposer substrate different from the main substrate 2001, and the memory controller 2002 and the plurality of semiconductor chips 2200 may be connected to each other by wiring formed on the interposer substrate.

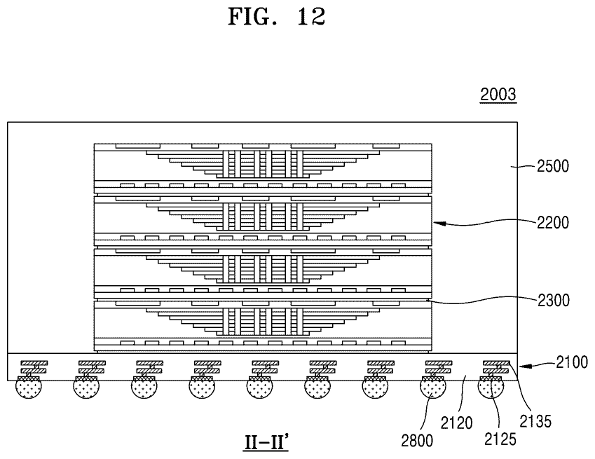

FIG. 12 is a schematic diagram showing semiconductor packages according to embodiments and is a cross-sectional view taken along a line II-II′ of FIG. 11.

Referring to FIG. 12, in the semiconductor package 2003, the package substrate 2100 may be a printed circuit board. The package substrate 2100 may include a package substrate body 2120, the plurality of package upper pads 2130 (refer to FIG. 11) located on the upper surface of the package substrate body 2120, a plurality of lower pads 2125 located on a lower surface of the package substrate body 2120 or exposed through the lower surface, and a plurality of internal wirings 2135 electrically connecting the plurality of package upper pads 2130 (refer to FIG. 11) to the plurality of lower pads 2125 in the package substrate body 2120. As shown in FIG. 11, the plurality of package upper pads 2130 may be electrically connected to the plurality of connection structures 2400. The plurality of lower pads 2125 may be connected to the plurality of wiring patterns 2005 on the main substrate 2001 of the data storage system 2000 shown in FIG. 11 through a plurality of conductive bumps 2800. Each of the plurality of semiconductor chips 2200 may include at least one of the semiconductor devices 10, 100, 100a, and 100b described with reference to FIGS. 1 to 8.

As above, embodiments have been disclosed in the drawings and specification. Although embodiments have been described in this specification using certain terms, this is used for the purpose of explaining the technical spirit of the inventive concept and is not used to limit the meaning or scope of the inventive concept as set forth in the disclosure. Therefore, those skilled in the art will understand that various modifications and other equivalent embodiments are possible therefrom.

While the inventive concept has been particularly shown and described with reference to embodiments thereof, it will be understood that various changes in form and details may be made therein without departing from the spirit and scope of the disclosure.

What is claimed is:

1. A semiconductor device comprising:
a peripheral circuit structure; and
a cell structure stacked on the peripheral circuit structure and including a cell region, a connection region, and a peripheral circuit connection region,
wherein the peripheral circuit connection region includes an inner region and an outer region surrounding the inner region, and
the cell structure includes:
gate electrodes apart from each other in a vertical direction in the cell region;
a channel structure passing through each of the gate electrodes to extend in the vertical direction in the cell region, the channel structure including a first end adjacent to the peripheral circuit structure and a second end opposite to the first end;
a stack insulating layer in the connection region and the peripheral circuit connection region, the stack insulating layer surrounding the gate electrodes;
a plug passing through the stack insulating layer in the inner region;
a conductive base layer on an upper surface of the stack insulating layer in the outer region and apart from the plug in a horizontal direction;
a cover insulating layer on an upper surface of the conductive base layer; and
a common source layer connected to the second end of the channel structure in the cell region and having a portion on an upper surface of the cover insulating layer.

2. The semiconductor device of claim 1, wherein
the portion of the common source layer has a first thickness in the vertical direction,
the cover insulating layer has a second thickness in the vertical direction,
the first thickness is about 30 nm to about 70 nm, and
the second thickness is about 1 nm to about 1 μm.

3. The semiconductor device of claim 2, wherein
the conductive base layer has a third thickness in the vertical direction,
the third thickness has a value y₁ (y₁ is a positive number) satisfying Equation 1 below,
x₁ has a value satisfying Equation 2 below, and
λ is about 300 nm to about 700 nm,
$${x}_{1} - 30 nm \leq {y}_{1} \leq {x}_{1} + 30 nm \qquad Equation 1$$
$$\frac{λ}{4} * 2 ( \frac{{x}_{1}}{( \frac{λ}{4 {x}_{1}} )} ) = \frac{2 n}{2} * λ \qquad Equation 2$$
where n is an integer equal to or greater than 1.

4. The semiconductor device of claim 3, wherein
the stack insulating layer has a fourth thickness in the vertical direction, and the fourth thickness is about 15 μm to about 30 μm.

5. The semiconductor device of claim 1,
further comprising an upper insulating pattern on the upper surface of the stack insulating layer in the inner region,
wherein the upper insulating pattern includes a silicon oxide film, a silicon nitride film, SiON, SiOCN, SiCN, or a combination thereof.

6. The semiconductor device of claim 5, wherein the plug further extends into the upper insulating pattern in the vertical direction.

7. The semiconductor device of claim 5, wherein
a material constituting the conductive base layer is different from a material constituting the upper insulating pattern, and
the conductive base layer includes amorphous silicon, single crystalline silicon, an amorphous carbon layer (ACL), or a combination thereof.

8. The semiconductor device of claim 1,
wherein at least one gate electrode of the gate electrodes is in the peripheral circuit connection region, and
wherein a vertical level of a lower surface of the cover insulating layer is lower than a vertical level of an upper surface of an uppermost gate electrode from among the at least one gate electrode in the peripheral circuit connection region.

9. The semiconductor device of claim 8,
wherein the conductive base layer has a thickness in the vertical direction,
the thickness has a value y₂ (y₂ is a positive number) satisfying Equation 3 below,
x₂ has a value satisfying Equation 4 below, and
λ is about 300 nm to about 700 nm,
$${x}_{2} - 30 nm \leq {y}_{2} \leq {x}_{2} + 30 nm \qquad Equation 3$$
$$\frac{λ}{4} * 2 ( \frac{{x}_{2}}{( \frac{λ}{4 {x}_{2}} )} ) = \frac{2 n - 1}{2} * λ \qquad Equation 4$$
where n is an integer equal to or greater than 1.

10. The semiconductor device of claim 1,
wherein the portion of the common source layer has a first thickness in the vertical direction,
the first thickness has a value y₃ (y₃ is a positive number) satisfying Equation 5 below,
x₃ has a value satisfying Equation 6 below, and
λ is about 300 nm to about 700 nm,
$${x}_{3} - 5 nm \leq {y}_{3} \leq {x}_{3} + 5 nm \qquad Equation 5$$
$$\frac{λ}{4} * 2 ( \frac{{x}_{3}}{( \frac{λ}{4 {x}_{3}} )} ) = \frac{2 n - 1}{2} * λ \qquad Equation 6$$
where n is an integer equal to or greater than 1.

11. A semiconductor device comprising:
a peripheral circuit structure; and
a cell structure stacked on the peripheral circuit structure and including a cell region, a connection region, and a peripheral circuit connection region,
wherein the peripheral circuit connection region includes an inner region and an outer region surrounding the inner region,
the cell structure includes:
gate electrodes apart from each other in a vertical direction in the cell region;
a channel structure passing through each of the gate electrodes to extend in the vertical direction in the cell region, the channel structure including a first end adjacent to the peripheral circuit structure and a second end opposite to the first end;
a stack insulating layer in the connection region and the peripheral circuit connection region, the stack insulating layer surrounding the gate electrodes and having a first thickness;
a conductive base layer on an upper surface of the stack insulating layer in the outer region;
a cover insulating layer on an upper surface of the conductive base layer, the cover insulating layer having a second thickness; and
a common source layer connected to the second end of the channel structure in the cell region and having a portion on an upper surface of the cover insulating layer, and
the second thickness is greater than the first thickness.

12. The semiconductor device of claim 11, wherein
the conductive base layer has a third thickness in the vertical direction,
the third thickness has a value y₂ (y₂ is a positive number) satisfying Equation 1 below,
x₂ has a value satisfying Equation 2 below, and
λ is about 300 nm to about 700 nm,
$${x}_{2} - 30 nm \leq {y}_{2} \leq {x}_{2} + 30 nm \qquad Equation 1$$
$$\frac{λ}{4} * 2 ( \frac{{x}_{2}}{( \frac{λ}{4 {x}_{2}} )} ) = \frac{2 n - 1}{2} * λ \qquad Equation 2$$
where n is an integer equal to or greater than 1.

13. The semiconductor device of claim 11, wherein the cell structure further includes:
an upper insulating pattern on the upper surface of the stack insulating layer in the inner region; and
a plug passing through the stack insulating layer and the upper insulating pattern in the inner region, and
wherein the plug further extends into the cover insulating layer in the vertical direction.

14. The semiconductor device of claim 13, wherein
the cell structure further includes a rear via inserted into the cover insulating layer and connected to the plug, and
the rear via is apart from the upper insulating pattern in the vertical direction.

15. The semiconductor device of claim 11,
wherein the portion of the common source layer has a fourth thickness in the vertical direction,
the fourth thickness has a value y₃ (y₃ is a positive number) satisfying Equation 3 below,
x₃ has a value satisfying Equation 4 below, and
λ is about 300 nm to about 700 nm,
$${x}_{3} - 5 nm \leq {y}_{3} \leq {x}_{3} + 5 nm \qquad Equation 3$$
$$\frac{λ}{4} * 2 ( \frac{{x}_{3}}{( \frac{λ}{4 {x}_{3}} )} ) = \frac{2 n - 1}{2} * λ \qquad Equation 4$$
where n is an integer equal to or greater than 1.

16. The semiconductor device of claim 11, wherein a vertical level of the upper surface of the cover insulating layer is lower than a vertical level of an upper surface of an uppermost gate electrode from among the gate electrodes.

17. The semiconductor device of claim 11, wherein the conductive base layer includes a material with an absorption coefficient equal to or greater than 0.

18. A semiconductor device comprising:
a peripheral circuit structure including a peripheral circuit transistor, a peripheral circuit wiring structure, and a first connection pad; and
a cell structure stacked on the peripheral circuit structure and including a cell region, a connection region, and a peripheral circuit connection region,
wherein the peripheral circuit connection region includes an inner region and an outer region surrounding the inner region,
wherein the cell structure further includes:
a second connection pad bonded to the first connection pad of the peripheral circuit structure;
gate electrodes and mold insulating layers alternately stacked one by one in a vertical direction on the second connection pad in the cell region;
a channel structure passing through the gate electrodes and mold insulating layers to extend in the vertical direction in the cell region, the channel structure including a first end adjacent to the peripheral circuit structure and a second end opposite to the first end, the channel structure protruding above an uppermost gate electrode from among the gate electrodes;
a common source layer in the cell region and being in contact with a channel layer of the channel structure protruding on the uppermost gate electrode;
a pad portion extending from the gate electrodes and having a stepwise shape in the connection region;
a first plug connected to the pad portion and passing through the pad portion to extend in the vertical direction;
a stack insulating layer surrounding the gate electrodes in the connection region and the peripheral circuit connection region;
a second plug passing through the stack insulating layer in the inner region;
a conductive base layer on an upper surface of the stack insulating layer in the outer region and apart from the second plug; and
a cover insulating layer on an upper surface of the conductive base layer.

19. The semiconductor device of claim 18,
wherein a portion of the common source layer is located on an upper surface of the cover insulating layer,
the portion of the common source layer has a first thickness,
the cover insulating layer has a second thickness,
the conductive base layer has a third thickness,
the first thickness is about 30 nm to about 70 nm,
the second thickness is about 1 nm to about 1 μm,
the third thickness has a value y₁ (y₁ is a positive number) satisfying Equation 1 below,
x₁ has a value satisfying Equation 2 below, and
λ is about 300 nm to about 700 nm,
$${x}_{1} - 30 nm \leq {y}_{1} \leq {x}_{1} + 30 nm \qquad Equation 1$$
$$\frac{λ}{4} * 2 ( \frac{{x}_{1}}{( \frac{λ}{4 {x}_{1}} )} ) = \frac{2 n}{2} * λ \qquad Equation 2$$
where n is an integer equal to or greater than 1.

20. The semiconductor device of claim 18, wherein a horizontal width of the first end is greater than a horizontal width of the second end.
